(19) United States
(12) Patent Application Publication
(10) Pub. No.: US 2026/0118446 A1
(43) Pub. Date: Apr. 30, 2026

(54) DEVICE FOR DETECTING A BACKSIDE THINNING OF AN ELECTRONIC DEVICE, AND METHODS OF MANUFACTURING AND USING

(71) Applicant: STMicroelectronics International N.V., Geneva (CH)

(72) Inventors: Carlos Augusto Suarez Segovia, Seyssinet-Pariset (FR); Benoit Froment, Grenoble (FR); Stephan Niel, Meylan (FR)

(21) Appl. No.: 19/340,036

(22) Filed: Sep. 25, 2025

(30) Foreign Application Priority Data
Oct. 29, 2024 (FR) 2411834

(51) Int. Cl. G01R 31/54; G01R 31/28; H01L 21/66

(52) U.S. Cl. CPC G01R 31/54; G01R 31/2884; H10P 74/277

(57) ABSTRACT

The present description concerns a detection device including a semiconductor region buried from a first surface of a semiconductor substrate of a first conductivity type, the buried semiconductor region being of a second conductivity type and being between a second surface of the semiconductor substrate and an electronic circuit, a first semiconductor region of the second conductivity type in an epitaxial layer having a first surface, and a second surface on a first surface of the semiconductor substrate, the first semiconductor region coupling the buried semiconductor region to a first node of a detection circuit via the first surface of the epitaxial layer, and a second semiconductor region of the second conductivity type in the epitaxial layer, the second semiconductor region coupling the buried semiconductor region to a second node of the detection circuit via the first surface of the epitaxial layer.

### CROSS-REFERENCE TO RELATED APPLICATIONS

This application claims priority to French patent application number FR2411834, filed on Oct. 29, 2024, which application is hereby incorporated herein by reference.

### TECHNICAL FIELD

The present disclosure generally concerns electronic devices, for example integrated circuits, and methods of manufacturing and using. The present disclosure concerns in particular the detection of a possible attack from the back side of an electronic device, for example of an integrated circuit.

The present disclosure applies, for example, to any attack implementing a technique of thinning of a portion of the back side of the integrated circuit, for example prior to a projection of a beam of electrically-charged particles (electrons or ions) onto the thinned portion.

### BACKGROUND

An integrated circuit is likely to be submitted to attacks by hackers, aiming at determining the structure of this integrated circuit, at extracting sensitive data therefrom, or even at modifying the operation thereof. Examples of sensitive data comprise codes or code fragments, encryption keys, or other data processed during a cryptographic operation.

An attack can be carried out from the back side of an integrated circuit equipped on its front side with electronic components such as transistors, diodes, capacitors, which electronic components may form an electronic circuit, or a plurality of electronic circuits, to be protected.

The front side is conventionally the side of the semiconductor substrate of the integrated circuit on which and/or from which the electronic components are formed, and above which is typically located an interconnection structure (usually designated by the acronym BEOL, for “Back End Of Line”). The back side of the semiconductor substrate is the side opposite to the front side of the semiconductor substrate. The semiconductor substrate may be made of one or a plurality of semiconductor layers.

During an attack, a portion of the back side of the semiconductor substrate may first be etched (thinned). Then, a smaller cavity, which may reach for example a surface area of 20×20 μm, may be formed into the etched (thinned) portion towards the front side. The cavity can typically be formed by projection of a beam of electrically-charged particles (electrons or ions) into the thinned portion from the back side. The beam may be an electron beam (E-beam). It can then be spoken of an E-beam technique. The beam may be an ion beam, for example positive ions in a focused ion beam (FIB) probe. Generally, a plurality of cavities are formed to access a plurality of electronic components or a plurality of electronic circuits. The cavities may extend approximately all the way to the level of wells having the electronic components formed therein, or all the way to the level of the electronic components, or all the way to conductive tracks coupled to the electronic components. Electrical contacts with the electronic components or the conductive tracks can then be created in these cavities, and hackers can use these contacts to analyze the electronic circuit in operation.

To access certain sensitive data, attacks generally have to be carried out while the integrated circuit is enabled, or at least while the targeted electronic circuit is enabled, that is, in operation.

Detection devices have already been provided to detect the presence of such attacks in operation. When an attack is detected by such a detection device, a countermeasure can be triggered, which may involve, for example, the destruction of the sensitive data and/or the disabling of the attacked electronic circuit. The electronic circuit may even be permanently disabled if, for example, a number of attacks are detected within a relatively short time interval.

A disadvantage of existing detection devices for detecting attacks is that they tend to be inefficient for certain types of attack, and/or to occupy a relatively large surface area in the integrated circuit.

It would be desirable to be able to improve, at least partly, known devices for detecting an attack on integrated circuits.

Advantageously, it would be desirable to have a detection device adapted to detecting a backside attack on an integrated circuit, which is efficient whatever the attack, and which occupies as little surface area as possible in the integrated circuit.

### SUMMARY

An embodiment overcomes all or part of the disadvantages of known devices for detecting attacks on integrated circuits.

An embodiment provides an electronic device comprising at least one electronic circuit and one detection device comprising:
a semiconductor region buried from a first surface of a semiconductor substrate of a first conductivity type, the buried semiconductor region being of the second conductivity type opposite to the first conductivity type, the buried semiconductor region being between a second surface of the semiconductor substrate, opposite to the first surface of the semiconductor substrate, and the at least one electronic circuit;
at least one first semiconductor region of the second conductivity type in an epitaxial semiconductor layer having a first surface, and a second surface opposite to the first surface of the epitaxial semiconductor layer and positioned on the first surface of the semiconductor substrate; the at least one first semiconductor region coupling the buried semiconductor region to a first node of a detection circuit via the first surface of the epitaxial semiconductor layer;
at least one second semiconductor region of the second conductivity type in the epitaxial semiconductor layer; the at least one second semiconductor region coupling the buried semiconductor region to a second node of the detection circuit via the first surface of the epitaxial semiconductor layer; and
the detection circuit, adapted to applying a voltage level or a current to the first node and to detecting with the second node the presence of an open circuit between the first and second nodes, so as to detect a thinning of the buried semiconductor region.

The epitaxial semiconductor layer is of the first conductivity type.

According to an embodiment, the at least one first semiconductor region comprises:
a first semiconductor well of the second conductivity type positioned from the first surface of the epitaxial semiconductor layer down to a non-zero first depth in the epitaxial semiconductor layer; and
a first buried semiconductor well of the second conductivity type extending in the epitaxial semiconductor layer from the first depth to the first surface of the semiconductor substrate, the first buried semiconductor well being in contact with the first semiconductor well and the buried semiconductor region; and
the at least one second semiconductor region comprises:
a second semiconductor well of the second conductivity type positioned from the first surface of the epitaxial semiconductor layer down to the first depth in the epitaxial semiconductor layer; and
a second buried semiconductor well of the second conductivity type extending in the epitaxial semiconductor layer from the first depth to the first surface of the semiconductor substrate, the second buried semiconductor well being in contact with the second semiconductor well and the buried semiconductor region;
the at least one electronic circuit being for example at a level located between the first and second buried semiconductor wells and the first surface of the epitaxial semiconductor layer.

The first depth is smaller than the thickness of the epitaxial semiconductor layer, so that the first and second semiconductor wells are at a non-zero distance from the second surface of the epitaxial semiconductor layer.

According to an embodiment, the first and second buried semiconductor wells are insulated from each other by a semiconductor portion of the epitaxial semiconductor layer which extends all the way to the first surface of the semiconductor substrate, the at least one electronic circuit being for example positioned between the semiconductor portion and the first surface of the epitaxial semiconductor layer.

According to an embodiment, the first and second semiconductor wells are insulated from each other by another semiconductor well of the first conductivity type, and, for example, also by an insulating trench located between the first surface of the epitaxial semiconductor layer and the other semiconductor well.

According to an embodiment, the semiconductor portion is located between the other semiconductor well and the buried semiconductor region.

According to an embodiment, the at least one second semiconductor region is electrically insulated from the at least one first semiconductor region.

According to an embodiment, the at least one electronic circuit is positioned in the epitaxial semiconductor layer.

According to an embodiment, the buried semiconductor region is under the at least one electronic circuit.

According to an embodiment, the detection device comprises:
a first electrical contact at the first surface of the epitaxial semiconductor layer coupling the at least one first semiconductor region to the first node;
a second electrical contact at the first surface of the epitaxial semiconductor layer coupling the at least one second semiconductor region to the second node.

According to an embodiment, the first electrical contact is in contact with the first semiconductor well, and the second electrical contact is in contact with the second semiconductor well.

According to an embodiment, the buried semiconductor region, the at least one first semiconductor region, and the at least one second semiconductor region:
are included in a semiconductor structure located in the semiconductor substrate and in the epitaxial semiconductor layer; and/or
form an electrical conduction channel coupled to the first and second nodes of the detection circuit, an open circuit between the first and second nodes being an open circuit in the electrical conduction channel, preferably in the buried semiconductor region.

According to an embodiment, the buried conductive region extends down to a depth greater than 2 μm, for example greater than or equal to 3 μm, for example greater than or equal to 4 μm.

According to an embodiment, the at least one electronic circuit comprises a plurality of electronic circuits configured in an array, the buried semiconductor region having a shape configured so that the buried semiconductor region runs beneath each of the electronic circuits of the array.

According to an embodiment, the buried conductive region has a zigzag shape, with a first end coupled to the at least one first semiconductor region and a second end coupled to the at least one second semiconductor region.

According to an embodiment, the electronic device is an integrated circuit.

An embodiment provides a method of use of the previously-described detection device, the method of use comprising:
the transmission of a voltage level or of a current at the first node;
the detection by the second node of the presence of an open circuit between the first and second nodes, so as to detect a thinning of the buried semiconductor region, for example in case of an attack from the second surface of the semiconductor substrate.

According to an embodiment, if the open circuit is detected, the detection circuit sends a signal to the at least one electronic circuit to disable it.

An embodiment provides a method of manufacturing an electronic device, the manufacturing method comprising:
a step of implantation from a first surface of a semiconductor substrate of a first conductivity type, so as to form a buried semiconductor region of the second conductivity type opposite to the first conductivity type, the buried semiconductor region being formed between a second surface of the semiconductor substrate, opposite to the first surface of the semiconductor substrate, and at least one electronic circuit;
a step of epitaxial growth on the first surface of the semiconductor substrate so as to form a doped epitaxial semiconductor layer of the first conductivity type, the epitaxial semiconductor layer having a first surface and a second surface opposite to the first surface of the epitaxial semiconductor layer and positioned on the first surface of the semiconductor substrate;
at least one step of implantation into the epitaxial semiconductor layer so as to form at least one first semiconductor region of the second conductivity type between the first surface of the semiconductor substrate and the first surface of the epitaxial semiconductor layer and at least one second semiconductor region of the second conductivity type between the first surface of the semiconductor substrate and the first surface of the epitaxial semiconductor layer, the at least one first and at least one second semiconductor regions each being coupled to the buried semiconductor region;
a step of coupling of the at least one first semiconductor region to a first node of a detection circuit via the first surface of the epitaxial semiconductor layer and the at least one second semiconductor region to a second node of the detection circuit via the first surface of the epitaxial semiconductor layer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A is a simplified and partial cross-section view illustrating a detection device according to an embodiment, adapted to detecting a backside attack on an integrated circuit;

FIG. 1B is a simplified and partial cross-section view illustrating an integrated circuit according to an embodiment, incorporating the detection device of FIG. 1A and an electronic circuit to be protected;

FIG. 1C is a simplified and functional view illustrating the integrated circuit of FIG. 1B;

FIG. 2 is a very simplified and partial top view illustrating an integrated circuit according to another embodiment; and

FIG. 3 shows a schematic and simplified example of a method of manufacturing the semiconductor structure of FIG. 1A.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the manufacturing steps and details of the semiconductor structure are described, being achievable with usual methods of manufacturing semiconductor structures formed inside and/or on top of a semiconductor substrate. Further, the manufacturing steps and details of the interconnection structure are not described, being achievable with usual interconnection structure manufacturing methods.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., or orientation qualifiers, such as the terms “horizontal”, “vertical”, “diagonal”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the following description, the terms “insulating” and “conductive” respectively signify, unless otherwise specified, electrically insulating and electrically conductive. Similarly, the term “insulate” signifies, unless otherwise specified, electrically insulate.

In the following description, unless otherwise specified, when reference is made to a substrate, reference is made to a semiconductor substrate, when reference is made to a well, reference is made to a semiconductor well, and when reference is made to a region, reference is made to a semiconductor region.

In the following description, unless otherwise specified, when reference is made to an epitaxial layer, it is referred to a semiconductor layer obtained by epitaxy, or epitaxial semiconductor layer.

In the following description, when reference is made to an attack detection device, or in short to an attack detector, reference is made to a device capable of detecting an attack on an electronic circuit, in particular an attack from the back side of the integrated circuit incorporating an electronic circuit to be protected from such an attack.

In the following description, by “buried”, there is meant buried deep into the semiconductor structure, that is, at a non-zero distance from the upper surface of the semiconductor structure, which may be buried deep into the semiconductor substrate or into the epitaxial layer.

In the following description, reference may be indifferently be made either to a doping type or a conductivity type, which designate either type P or type N.

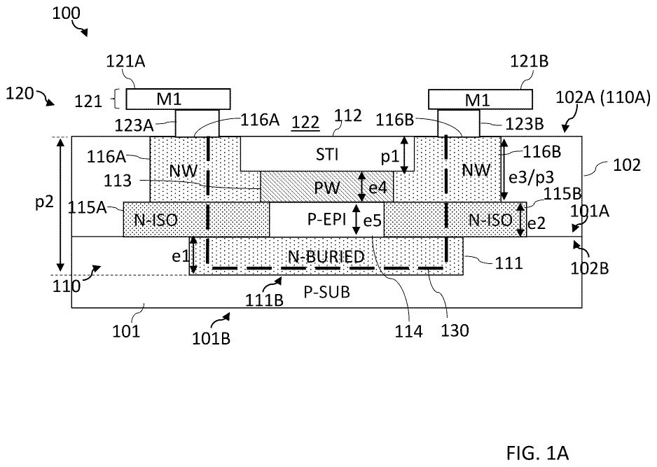

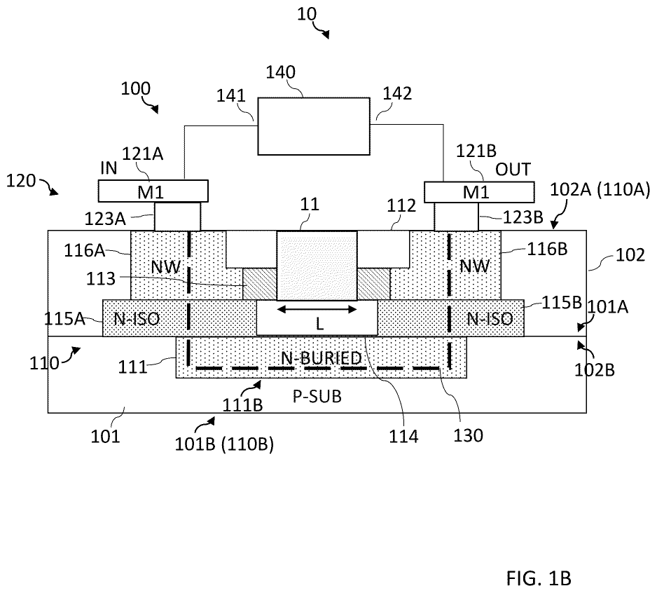

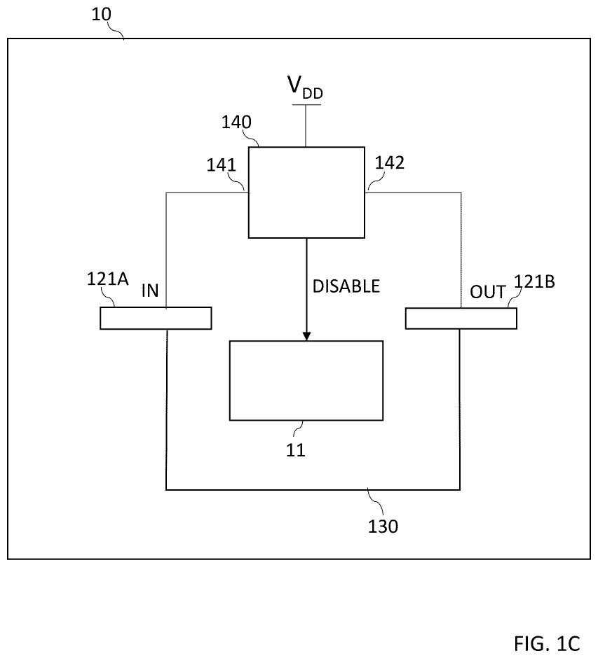

FIG. 1A is a partial simplified cross-section view illustrating a detection device 100 according to an embodiment adapted to detecting a backside attack on an integrated circuit 10. FIG. 1B is a simplified and partial cross-section view illustrating an integrated circuit 10 incorporating the detection device 100 of FIG. 1A and an electronic circuit 11 to be protected. FIG. 1C is a simplified and functional view illustrating the integrated circuit 10 of FIG. 1B.

In the example shown in FIGS. 1A and 1B, detection device 100 comprises a semiconductor structure 110 formed in a semiconductor substrate 101 (P-SUB) and in an epitaxial layer 102 (P-EPI) made of a semiconductor material, positioned on the upper surface 101A of semiconductor substrate 101. The lower surface 102B of epitaxial layer 102 is in contact with the upper surface 101A of substrate 101. The lower surface 101B of semiconductor substrate 101 corresponds to the lower face, or back side, 110B of semiconductor structure 110. This also corresponds to the back side of integrated circuit 10.

The upper surface 110A, or front side, of semiconductor structure 110 corresponds to the upper surface 102A of epitaxial layer 102, which is the surface opposite to the lower surface 102B of epitaxial layer 102. The upper surface 110A of semiconductor structure 110 corresponds to the surface from which an interconnection structure 120, described hereafter, is positioned and/or on which electrical contacts 123A, 123B, described later, are positioned.

Semiconductor substrate 101 is for example made of silicon or corresponds to the semiconductor layer of a substrate of silicon-on-insulator (SOI) type.

Semiconductor substrate 101 is doped with a first conductivity type, in this example type P.

Epitaxial layer 102 is for example made of silicon.

Epitaxial layer 102 is doped, for example lightly doped, with the first doping type, in the example type P.

Semiconductor structure 110 may be a silicon structure.

Semiconductor structure 110 comprises a buried semiconductor region 111 (N-BUR) formed in semiconductor substrate 101 and doped with the second doping type, opposite to the first doping type. In the shown example, the second doping type is type N.

For example, buried semiconductor region 111 is flush with the upper surface 101A of semiconductor substrate 101. For example, buried semiconductor region 111 extends down to a depth smaller than the thickness of semiconductor substrate 101, that is, has a thickness e1 smaller than the thickness of semiconductor substrate 101.

Semiconductor structure 110 further comprises, in epitaxial layer 102:
an insulating trench 112 (STI), for example of shallow insulating trench type, known under the term STI, for “Shallow Trench Isolation”, formed from the upper surface 102A of epitaxial layer 102: the depth p1 of insulating trench 112 is smaller than the thickness of epitaxial layer 102;
a semiconductor well 113 (PW) located in epitaxial layer 102 under insulating trench 112: semiconductor well 113 is more heavily doped with the first doping type than epitaxial layer 102, in the example type P;
a doped semiconductor portion 114 of epitaxial layer 102, of the first doping type, between semiconductor well 113 and buried semiconductor region 111;
semiconductor wells 115A, 115B (N-ISO) buried from a non-zero depth p3 of the upper surface 102A of epitaxial layer 102, the buried semiconductor wells 115A, 115B being doped with the second doping type, in the example type N, and being on either side of, for example around, portion 114 of epitaxial layer 102; and
doped semiconductor wells 116A, 116B (NW) of the second doping type, in the example type N, around insulating trench 112 and semiconductor well 113.

Preferably, the buried semiconductor wells 115A, 115B are insulated from each other. Preferably, the semiconductor wells 116A, 116B are insulated from each other.

P-type semiconductor well 113 is for example narrower than insulating trench 112, and for example centered with respect to insulating trench 112, but this is not limiting.

Each buried semiconductor well 115A, 115B is positioned on top of, and in contact with, buried semiconductor region 111. For example, semiconductor portion 114 is narrower than buried semiconductor region 111, so that each buried semiconductor well 115A, 115B comprises areas of contact with buried semiconductor region 111. In the example shown in FIGS. 1A and 1B, the buried semiconductor wells 115A, 115B are substantially centered with respect to buried semiconductor region 111. As a variant, the buried semiconductor wells 115A, 115B may not be centered with respect to buried semiconductor region 111.

Each semiconductor well 116A, 116B is in contact with one of the buried semiconductor wells 115A, 115B: semiconductor well 116A is in contact with buried semiconductor well 115A, and semiconductor well 116B is in contact with buried semiconductor well 115B. In the example shown in FIGS. 1A and 1B, each semiconductor well 116A, 116B extends from the upper surface 102A of epitaxial layer 102 in depth (depth p3) down to the level of buried semiconductor wells 115A, 115B.

Semiconductor wells 116A, 116B, buried semiconductor wells 115A, 115B, and buried semiconductor region 111, which are all N-doped, form an electrical continuity, or an electrical conduction channel, of detection device 100, as explained later.

Semiconductor wells 116A, 116B, buried semiconductor wells 115A, 115B, and buried semiconductor region 111 are thus configured to ensure an electrical continuity.

Each semiconductor well 116A, 116B may have various shapes, for example a square or rectangular shape, an oval or circular shape, a U shape.

Each buried semiconductor well 115A, 115B may have various shapes, for example a square or rectangular shape, an oval or circular shape, a U shape.

For example, each buried semiconductor well 115A, 115B has a square shape with a 1.8-μm side length, that is, a surface footprint of 3.24 μm². For example, two buried semiconductor wells 115A and 115B may be used, having a total surface footprint of 2 times 3.24 μm², that is, a little less than 6.5 μm². Semiconductor wells 116A, 116B may be configured so that they have a smaller footprint than buried semiconductor wells 115A, 115B.

Buried semiconductor region 111 may have various shapes, for example the shape of a ring or of a partial ring, a U shape, a spiral shape, a zigzag shape, a square or rectangular shape. Buried semiconductor region 111 is preferably continuous.

The lower surface 111B of buried semiconductor region 111 is, for example, at a depth p2 in the range from 3.6 to 5 μm below the upper surface 110A of semiconductor structure 110. Buried semiconductor region 111 has, for example, a thickness e1 in the range from 1 to 3 μm.

Each buried semiconductor well 115A, 115B for example has a thickness e2 in the range from 1 to 3 μm, and each semiconductor well 116A, 116B, for example, has a thickness e3 in the range from 1 to 2 μm. Thickness e3 is equal to depth p3.

The depth p1 of insulating trench 112 is for example in the range from 0.3 to 0.5 μm. The thickness e4 of semiconductor well 113 is, for example, in the range from 0.3 to 1.3 μm. Semiconductor portion 114 has a thickness e5 for example greater than or equal to 1 μm.

In semiconductor structure 110, PN junctions of polarities opposite to those of P-type semiconductor well 113 and of P-type semiconductor portion 114, respectively formed with N-type semiconductor wells 116A, 116B and buried semiconductor wells 115A, 115B, enable to electrically insulate the P-type semiconductor well 113 and the P-type semiconductor portion 114, the P-type semiconductor well 113 being further insulated by insulating trench 112. An electrical conduction channel 130 which comprises semiconductor well 116A, buried semiconductor well 115A, buried semiconductor region 111, buried semiconductor well 115B, and semiconductor well 116B is thus obtained. In other words, N-type semiconductor regions 111, 115A, 115B, 116A, 116B, insulated from the other regions which are either of type P, or insulating, form an insulated electrical conduction channel 130 in semiconductor structure 110.

Electrical conduction channel 130 is symbolized by a path in dotted lines which enables to visualize a conductive path, among a plurality of possible conductive paths along electrical conduction channel 130. Electrical conduction channel 130 is thus not limited to this path in dotted lines.

Such a semiconductor structure 110 enables to have a buried semiconductor region 111 which reaches a significant depth, typically greater than 2 μm, for example greater than 3 μm, for example in the range from 3.6 μm to 5 μm, and which is comprised in electrical conduction channel 130, which channel may comprise contact points on the upper surface 110A of semiconductor structure 110, at the level of semiconductor wells 116A, 116B. As will be explained later, this enables to detect an attack in depth from the back side of integrated circuit 10, well before electronic circuit 11 is reached, the electronic circuit 11 to be protected being above buried semiconductor region 111, buried semiconductor region 111 thus being under the electronic circuit 11 to be protected, that is, between the back side 101B of integrated circuit 10 and electronic circuit 11.

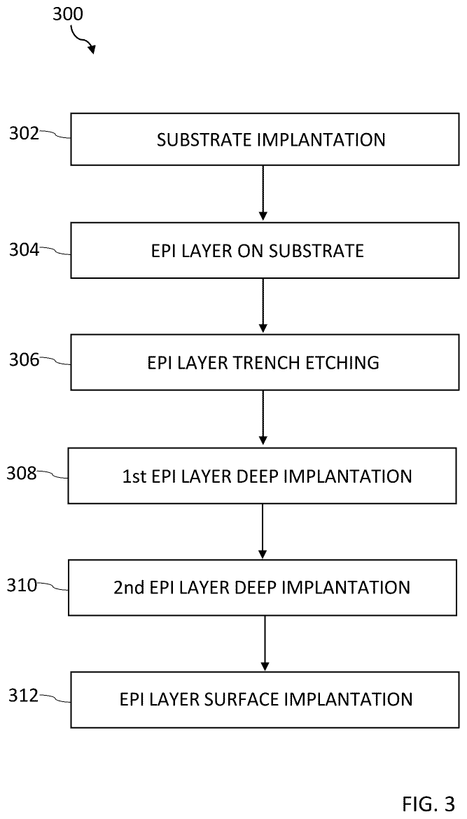

FIG. 3 illustrates in simplified and schematic fashion an example of a method 300 of manufacturing the semiconductor structure 110 of FIG. 1A.

Manufacturing method 300 comprises:
a step 302 of implantation (SUBSTRATE IMPLANTATION) from the upper surface 101A of semiconductor substrate 101 to form buried semiconductor region 111, this implantation being of the second doping type, opposite to the doping type of semiconductor substrate 101, in this example the implantation is of type N: this implantation may be preceded by the forming of a mask to mask the areas of semiconductor substrate 101 which are not to be N-doped;
a step 304 of epitaxial growth (EPI LAYER ON SUBSTRATE) from the upper surface 101A of semiconductor substrate 101 to form doped epitaxial layer 102, for example lightly doped, of the first doping type, in this example of type P;
an etch step 306 (EPI LAYER TRENCH ETCHING) from the upper surface 102A of epitaxial layer 102 to form a shallow trench in epitaxial layer 102, and then a filling of this trench, for example made of silicon oxide, to form insulating trench 112;
a step 308 (1st EPI LAYER DEEP IMPLANTATION) of deep implantation in epitaxial layer 102 through insulating trench 112 to form semiconductor well 113, this implantation being of the first doping type, in this example of type P, this implantation being for example carried out so as to preserve the semiconductor portion 114 of epitaxial layer 102 between semiconductor well 113 and buried semiconductor region 111;
a deep implantation step 310 (2nd EPI LAYER DEEP IMPLANTATION) in epitaxial layer 102, from the lower level of semiconductor well 113 to the upper surface 101A of semiconductor substrate 101, and around the semiconductor portion 114 of epitaxial layer 102, to form buried semiconductor wells 115A, 115B, this implantation being of the second doping type, in this example of type N;
an implantation step 312 (EPI LAYER SURFACE IMPLANTATION) from the upper surface 102A of epitaxial layer 102 to buried semiconductor wells 115A, 115B, around insulating trench 112 and semiconductor well 113, to form semiconductor wells 116A, 116B, this implantation being of the second doping type, in this example of type N.

Semiconductor wells 116A, 116B are implanted with an energy enabling to reach in depth buried semiconductor wells 115A, 115B, so as to form, with buried semiconductor wells 115A, 115B, continuous N-type semiconductor regions insulating P-type semiconductor well 113.

An interconnection structure 120 may be positioned above semiconductor structure 110, above epitaxial layer 102, for example on the upper surface 102A of epitaxial layer 102. The interconnection structure is generally referred to as a “BEOL”, for “back end of line” interconnection structure.

A metallization level M1 of interconnection structure 120, which generally comprises a plurality of metallization levels, has been shown. This metallization level M1 comprises a plurality of conductive segments 121A, 121B of a conductive layer 121, for example a metal layer, each conductive segment 121A, 121B forming a conductive track, for example a metal track.

Interconnection structure 120 further comprises an insulating layer 122, which is generally a stack of a plurality of insulating layers, separating the different metallization levels and the different conductive tracks of the same metallization level, conductive tracks 121A, 121B thus being embedded in insulating layer 122. Insulating layer 122 may be made of an oxide, for example a silicon oxide.

Each conductive track 121A, 121B of interconnection structure 120 is coupled to semiconductor structure 110 by an electrical contact 123A, 123B (contact), or any other electrical connection element, for example a conductive via. For example, contacts 123A, 123B are part of interconnection structure 120.

Contacts 123A, 123B are coupled, for example connected, to the upper surface 110A of semiconductor structure 110, which corresponds to the upper surface 102A of epitaxial layer 102. In particular, contacts 123A, 123B are each coupled, for example connected, to one of the semiconductor wells 116A, 116B of semiconductor structure 110. Thus, each semiconductor well 116A, 116B is coupled to one of the conductive tracks 121A, 121B of interconnection structure 120 via one of contacts 123A, 123B.

The electrical conduction channel 130 formed by the N-type semiconductor regions 111, 115, 116 of semiconductor structure 110 is thus coupled to conductive tracks 121A, 121B via contacts 123A, 123B. The connection to the first metallization level M1 has been shown, but a connection to any other metallization level could be contemplated.

As shown in FIG. 1B, integrated circuit 10 comprises an electronic circuit 11 positioned above buried semiconductor region 111.

Electronic circuit 11 for example comprise standard cells, transistors, diodes, resistors, and/or capacitors.

In the example shown in FIG. 1B, electronic circuit 11 is positioned in height at a level just above the level of buried semiconductor wells 115A, 115B (these buried semiconductor wells 115A, 115B being laterally positioned on either side of electronic circuit 11), and P-type semiconductor portion 114 is located below electronic circuit 11. P-type semiconductor portion 114 can ensure an insulation between buried semiconductor region 111 and electronic circuit 11, which may be advantageous if, for example, electronic circuit 11 is formed in an N-type well, for example of N-ISO type.

Semiconductor wells 116A, 116B are for example formed substantially flush with electronic circuit 11, for example on either side of electronic circuit 11.

Further, electronic circuit 11 may be positioned within P-type semiconductor well 113 and insulating trench 122, so as to also be insulated, for example if it is formed in an N-type well, for example of N-ISO type.

Conductive tracks 121A, 121B, and thus electrical conduction channel 130, may be coupled to a detection circuit 140, shown in FIGS. 1B and 1C. For example, conductive track 121A may be coupled to a first node 141 of detection circuit 140, and conductive track 121B may be coupled to a second node 142 of detection circuit 140. For example, conductive track 121A forms an input (IN) from detection circuit 140 and conductive track 121B forms an output (OUT) towards detection circuit 140.

Detection circuit 140 is coupled to a voltage supply V_{DD} to supply electrical conduction channel 130 via conductive tracks 121A, 121B.

As a variant, it may be possible to directly couple detection circuit 140 to contacts, for example contacts 123A, 123B, to semiconductor wells 116A, 116B, without for these contacts to necessarily form part of an interconnection structure. For example, contact 123A forms an input (IN) from detection circuit 140 and contact 123B forms an output (OUT) towards detection circuit 140.

Detection circuit 140 may be configured to detect a break in electrical continuity in electrical conduction channel 130, which may be due to a thinning, for example by etching, in buried semiconductor layer 111. Thus, detection circuit 140 is configured to detect a backside attack.

In operation, a power supply voltage V_{DD} is applied by detection circuit 140 to input IN, inducing a current in electrical conduction channel 130, and detection circuit 140 detects at output OUT the break in electrical continuity.

The break in electrical continuity may be detected by a measurement of the resistance in electrical conduction channel 130. For example, the detection circuit may be configured to detect a resistance increase in electrical conduction channel 130, when an etching by thinning of buried semiconductor layer 111 is undertaken, or even an infinite resistance when buried semiconductor layer 111 is etched across its entire thickness, interrupting electrical conduction channel 130 in semiconductor structure 110. A high resistance limit may be defined to determine whether an attack is taking place.

According to an alternative embodiment, a plurality of electrical conduction channels of the type of electrical conduction channel 130 could each be connected between two inverters so as to form a ring oscillator, the frequency of which would be measured. An attack on one of these electrical conduction channels would induce an increase in the resistance thereof, which would cause a decrease in the oscillation frequency of the ring oscillator. If one of these electrical conduction channels was completely destroyed, the resistance of this channel would become infinite, and the oscillator frequency would drop to zero. It would also be possible to define a low frequency, from which the channel would be considered to be under attack.

In case of detection of a change in the electrical parameter, detection circuit 140 may send a signal DISABLE to electronic circuit 11 to disable it, and/or to delete sensitive data.

As indicated hereabove, the buried semiconductor region may reach a depth greater than 2 μm, or 3 μm, or even greater than 3.6 μm, for example up to 5 μm. Thus, detection device 100 can detect an attack at a depth ranging up to 5 μm, or at least well before electronic circuit 11 is reached. Indeed, an Ebeam-type attack, or even an FIB-type attack, can generally not be performed down to a depth greater than approximately 1 μm, which requires a thinning, or etching, from the back side to reach this depth. Detection device 100 can thus detect an attack, by detecting a backside thinning.

Further, a relatively large surface area of detection of an attack, for example an Ebeam-type or even FIB-type attack, can be covered with a limited surface footprint of detection device 100. For example, a detection length L which may range up to 200 μm can be covered. For example, two buried semiconductor wells 115A, 115B, having a surface footprint of little less than 6.5 μm² as indicated above, coupled to buried semiconductor region 111 having a length equal to detection length L plus a length of contact with each buried semiconductor well 115A, 115B, this contact length being smaller than or equal to twice the side of the buried semiconductor wells 115A, 115B, that is, 3.6 μm, may be formed.

The Inventors have determined that, for a buried semiconductor layer 111 with a 0.75-μm width and a 200-μm length, the total resistance of the buried semiconductor layer was smaller than 15 kOhms, which enables to have a significant detection length, in the order of 200 μm, without for all this creating a too high resistance in electrical conduction channel 130.

FIGS. 1A and 1B illustrate an example of a semiconductor structure formed in a semiconductor substrate and in an epitaxial layer on the semiconductor substrate. This example of semiconductor structure is not limiting, other semiconductor structures formed in a semiconductor substrate and an epitaxial layer on the semiconductor substrate can be contemplated by those skilled in the art.

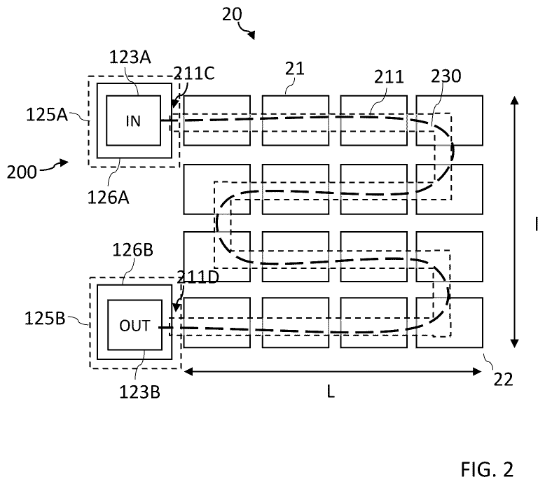

FIG. 2 is a very simplified and partial top view illustrating an integrated circuit 20 according to another embodiment.

The integrated circuit 20 of FIG. 2 has many elements in common with the integrated circuit 10 of FIG. 1B, and only the differences between the two integrated circuits are detailed in the following description.

The integrated circuit 20 of FIG. 2 differs from the integrated circuit 10 of FIG. 1B mainly in that it comprises a plurality of electronic circuits 21, instead of a single electronic circuit 11 in FIG. 1B. The electronic circuits 21 in the figure are arranged in an array 22, in this example a 4×4 array, although this is not limiting. The length L of the array is, for example, equal to 20 μm. The width l of the array is, for example, equal to 20 μm. Thus, FIG. 2 could correspond to a top view of FIG. 1B, electronic circuit 11 then representing the array 22 of electronic circuits 21 of FIG. 2.

Further, instead of conductive tracks 121A, 121B, contacts 123A, 123B have been directly shown.

Contacts 123A, 123B may be formed on the semiconductor wells 116A, 116B described in relation with FIG. 1A, themselves in contact with the buried semiconductor wells 115A, 115B described in relation with FIG. 1A, themselves in contact with buried semiconductor region 211, which is shown in transparency and in dotted lines, under the array 22 of electronic circuits 21. It can be seen in this example that buried semiconductor region 211 has a zigzag, or meandering, shape, with one end 211C coupled to contact 123A (via buried semiconductor well 115A and semiconductor well 116A) and another end 211D coupled to contact 123B (via buried semiconductor well 115B and semiconductor well 116B), so as to be able to be under each electronic circuit 21. Electrical conduction channel 230 follows the zigzag-shaped buried semiconductor region 211. A backside attack on integrated circuit 20 under any electronic circuit 21 can thus be detected.

The detection device 200 of this embodiment enables to cover the entire network 22 of electronic circuits 21, for example over a surface area of 20 μm×20 μm, enabling, for example, to thwart an Ebeam attack.

Those skilled in the art may envisage other types of arrays of electronic circuit, and other adapted detection devices, in particular other shapes of buried semiconductor region.

The embodiments enable to detect deep attacks from the back side of an electronic device, for example an integrated circuit, by positioning an electronic circuit to be protected above a buried semiconductor layer formed in a semiconductor substrate.

In the described embodiments, it can be seen that the detection device can be formed using manufacturing techniques of microelectronics, for example already-existing manufacturing processes to form the described semiconductor structure, by positioning the electronic circuit to be protected above the buried semiconductor layer. For example, the detection device may be formed by adding few complementary steps, or even without adding any, since it is already planned to manufacture the described semiconductor structure.

The embodiments described hereinafter are particularly adapted to the detection of a backside attack on an integrated circuit, in particular any attack implementing a technique for thinning a portion of the back side of the integrated circuit, for example prior to a projection of a beam of electrically-charged particles (electrons or ions) onto the thinned portion.

The above-described embodiments can be used in many types of industrial markets, particularly for embedded security systems. The market of embedded security is rapidly evolving, from a traditional smart card activity to a wide range of connected devices associated with a rapidly expanding communications infrastructure. In this booming digital economy, data are becoming a strategic asset. But as data travel from sensors to gateways, servers, and finally to clouds, they are increasingly exposed to new threats. These new challenges call for new security approaches in a variety of sectors, such as for example:
the automotive industry, for example in the field of secure car access, secure electronic portals, wireless charging . . . ;
the industrial sector, for example in the field of on-board security, secure connections, or secure authentication, in the field of infrastructure electrification, of the Internet of Things (IoT) and of smart homes;
the personal electronics industry, for example in the field of banking, identification, mobile telephony, and the Internet of Things (IoT), as well as in high-speed interfaces;
the communications equipment, brand protection, computer and peripherals industry, for example in the field of infrastructure and data centers, and in the field of low earth orbit (LEO) satellites.

Various embodiments and variants have been described. Those skilled in the art will understand that certain features of these various embodiments and variants may be combined, and other variants will occur to those skilled in the art. For example, while an N-type buried semiconductor region in a P-type silicon semiconductor substrate has been described (that is, the first doping type, or conductivity type, is type P), it will clearly occur to those skilled in the art that, in alternative embodiments, opposite conductivity types could be used for the buried semiconductor region and the semiconductor substrate, the buried semiconductor region then being of type P and the semiconductor substrate being of type N (that is, the first doping type, or conductivity type, is of type N). Those skilled in the art will be capable of adapting the doping type of the semiconductor wells and semiconductor regions in the semiconductor structure. For example, the electrical conduction channel would then be of type P, instead of type N.

For example, the embodiments describe an integrated circuit, although it could be any other electronic device incorporating at least one electronic circuit to be protected from an attack.

Finally, the practical implementation of the described embodiments and variants is within the abilities of those skilled in the art based on the functional indications given hereabove.

What is claimed is:

1. An electronic device comprising:
at least one electronic circuit; and
a detection device comprising:
a semiconductor region buried from a first surface of a semiconductor substrate of a first conductivity type, the buried semiconductor region being of a second conductivity type opposite to the first conductivity type, the buried semiconductor region being between a second surface of the semiconductor substrate, opposite to the first surface of the semiconductor substrate, and the at least one electronic circuit;
at least one first semiconductor region of the second conductivity type in an epitaxial semiconductor layer having a first surface, and a second surface opposite to the first surface of the epitaxial semiconductor layer, the epitaxial semiconductor layer positioned on the first surface of the semiconductor substrate, and the at least one first semiconductor region coupling the buried semiconductor region to a first node of a detection circuit via the first surface of the epitaxial semiconductor layer;
at least one second semiconductor region of the second conductivity type in the epitaxial semiconductor layer, the at least one second semiconductor region coupling the buried semiconductor region to a second node of the detection circuit via the first surface of the epitaxial semiconductor layer; and
the detection circuit, configured to:
apply a voltage level or a current to the first node; and
detect with the second node a presence of an open circuit between the first and second nodes, so as to detect a thinning of the buried semiconductor region.

2. The electronic device according to claim 1, wherein:
the at least one first semiconductor region comprises:
a first semiconductor well of the second conductivity type positioned from the first surface of the epitaxial semiconductor layer down to a first non-zero depth in the epitaxial semiconductor layer; and
a first buried semiconductor well of the second conductivity type extending in the epitaxial semiconductor layer from the first non-zero depth to the first surface of the semiconductor substrate, the first buried semiconductor well being in contact with the first semiconductor well and the buried semiconductor region; and
the at least one second semiconductor region comprises:
a second semiconductor well of the second conductivity type positioned from the first surface of the epitaxial semiconductor layer down to the first non-zero depth in the epitaxial semiconductor layer; and
a second buried semiconductor well of the second conductivity type extending into the epitaxial semiconductor layer from the first non-zero depth to the first surface of the semiconductor substrate, the second buried semiconductor well being in contact with the second semiconductor well and the buried semiconductor region;
wherein the at least one electronic circuit is at a physical level located between the first and second buried semiconductor wells and the first surface of the epitaxial semiconductor layer.

3. The electronic device according to claim 2, wherein the first and second buried semiconductor wells are insulated from each other by a semiconductor portion of the epitaxial semiconductor layer that extends to the first surface of the semiconductor substrate, wherein the at least one electronic circuit is positioned between the semiconductor portion and the first surface of the epitaxial semiconductor layer.

4. The electronic device according to claim 2, wherein the first and second semiconductor wells are insulated from each other by another semiconductor well of the first conductivity type, and also by an insulating trench located between the first surface of the epitaxial semiconductor layer and the another semiconductor well.

5. The electronic device according to claim 4, wherein a semiconductor portion, of the epitaxial semiconductor layer that extends to the first surface of the semiconductor substrate, is located between the another semiconductor well and the buried semiconductor region.

6. The electronic device according to claim 1, wherein:
the at least one second semiconductor region is electrically insulated from the at least one first semiconductor region; and/or
the at least one electronic circuit is positioned in the epitaxial semiconductor layer; and/or
the buried semiconductor region underlies the at least one electronic circuit.

7. The electronic device according to claim 2, wherein the detection device comprises:
a first electrical contact at the first surface of the epitaxial semiconductor layer coupling the at least one first semiconductor region to the first node; and
a second electrical contact at the first surface of the epitaxial semiconductor layer coupling the at least one second semiconductor region to the second node.

8. The electronic device according to claim 7, wherein the first electrical contact is in contact with the first semiconductor well, and the second electrical contact is in contact with the second semiconductor well.

9. The electronic device according to claim 1, wherein the buried semiconductor region, the at least one first semiconductor region, and the at least one second semiconductor region:
are included in a semiconductor structure located in the semiconductor substrate and in the epitaxial semiconductor layer; and/or
form an electrical conduction channel coupled to the first and second nodes of the detection circuit, the open circuit between the first and second nodes being in the electrical conduction channel in the buried semiconductor region.

10. The electronic device according to claim 9, wherein the buried conduction channel extends down to a depth greater than 2 μm.

11. The electronic device according to claim 10, wherein the depth is greater than or equal to 3 μm.

12. The electronic device according to claim 1, wherein the at least one electronic circuit comprises a plurality of electronic circuits configured in an array, the buried semiconductor region having a shape configured so that the buried semiconductor region runs beneath each of the electronic circuits of the array.

13. The electronic device according to claim 9, wherein the buried conduction channel has a zigzag shape, with a first end coupled to the at least one first semiconductor region and a second end connected to the at least one second semiconductor region.

14. The electronic device according to claim 1, wherein the electronic device is an integrated circuit.

15. A method of using an electronic device, the electronic device comprising at least one electronic circuit and a detection device, the detection device comprising a semiconductor region buried from a first surface of a semiconductor substrate of a first conductivity type, the buried semiconductor region being of a second conductivity type opposite to the first conductivity type, the buried semiconductor region being between a second surface of the semiconductor substrate, opposite to the first surface of the semiconductor substrate, and the at least one electronic circuit, at least one first semiconductor region of the second conductivity type in an epitaxial semiconductor layer having a first surface, and a second surface opposite to the first surface of the epitaxial semiconductor layer, the epitaxial semiconductor layer positioned on the first surface of the semiconductor substrate, and the at least one first semiconductor region coupling the buried semiconductor region to a first node of a detection circuit via the first surface of the epitaxial semiconductor layer, at least one second semiconductor region of the second conductivity type in the epitaxial semiconductor layer, the at least one second semiconductor region coupling the buried semiconductor region to a second node of the detection circuit via the first surface of the epitaxial semiconductor layer, and the detection circuit, the method comprising:
applying, by the detection circuit, a voltage level or a current to the first node; and
detecting, by the detection circuit with the second node, a presence of an open circuit between the first and second nodes, so as to detect a thinning of the buried semiconductor region.

16. The method according to claim 15, wherein the thinning of the buried semiconductor region is caused by an attack from the second surface of the semiconductor substrate.

17. The method according to claim 15, further comprising, in response to detecting the open circuit, sending, by the detection circuit, a signal to the at least one electronic circuit to disable the at least one electronic circuit.

18. A method of manufacturing an electronic device, the method comprising:
implanting from a first surface of a semiconductor substrate of a first conductivity type, so as to form a buried semiconductor region of a second conductivity type opposite to the first conductivity type, the buried semiconductor region being formed between a second surface of the semiconductor substrate, opposite to the first surface of the semiconductor substrate, and at least one electronic circuit;
causing epitaxial growth on the first surface of the semiconductor substrate so as to form a doped epitaxial semiconductor layer of the first conductivity type, the epitaxial semiconductor layer having a first surface and a second surface opposite to the first surface of the epitaxial semiconductor layer, the epitaxial semiconductor layer positioned on the first surface of the semiconductor substrate;
implanting in the epitaxial semiconductor layer so as to form at least one first semiconductor region of the second conductivity type between the first surface of the semiconductor substrate and the first surface of the epitaxial semiconductor layer, and at least one second semiconductor region of the second conductivity type between the first surface of the semiconductor substrate and the first surface of the epitaxial semiconductor layer, the at least one first and at least one second semiconductor region each being coupled to the buried semiconductor region;
connecting the at least one first semiconductor region to a first node of a detection circuit via the first surface of the epitaxial semiconductor layer; and
connecting the at least one second semiconductor region to a second node of the detection circuit via the first surface of the epitaxial semiconductor layer.

19. The method according to claim 18, wherein the implanting in the epitaxial semiconductor layer comprises a plurality of implanting steps.

20. The method according to claim 18, further comprising:
insulating the first and second buried semiconductor wells from each other by a semiconductor portion of the epitaxial semiconductor layer that extends to the first surface of the semiconductor substrate; and
positioning the at least one electronic circuit between the semiconductor portion and the first surface of the epitaxial semiconductor layer.
